(19) United States
(12) Patent Application Publication
(10) Pub. No.: US 2015/0323830 A1
(43) Pub. Date: Nov. 12, 2015

(54) DISPLAY PANEL AND A METHOD FOR CUTTING THE SAME

(71) Applicant: InnoLux Corporation, Miao-Li County (TW)

(72) Inventors: Huan-Kaung PENG, Miao-Li County (TW); Wei-Ti WANG, Miao-Li County (TW); Hsin-Hsu SHEN, Miao-Li County (TW); Yan-Li WANG, Miao-Li County (TW); Wei ZHANG, Miao-Li County (TW); Shih-Hsiung WU, Miao-Li County (TW)

(21) Appl. No.: 14/678,175

(22) Filed: Apr. 3, 2015

Related U.S. Application Data
(60) Provisional application No. 61/991,254, filed on May 9, 2014.

(30) Foreign Application Priority Data
Jul. 9, 2014 (TW) 103123592

(51) Int. Cl. G02F 1/1333; B26D 3/10; H01L 21/78; B32B 3/02

(52) U.S. Cl. CPC G02F 1/133351; B32B 3/02; B26D 3/10; H01L 21/78; B32B 2250/02; B32B 2457/20

(57) ABSTRACT

A display panel and a method for cutting the same are disclosed. The display panel of the present invention comprises: a first substrate comprising at least a first side, a first edge, and a turning edge connecting the first side and the first edge, wherein the turning edge has a curve shape; and a second substrate disposed opposite to the first substrate and comprising at least a second edge partially overlapped with the first edge, wherein the second substrate is protruded from the turning edge at a region near to the turning edge of the first substrate, wherein a virtual extension line of the first side and the second edge intersect at an intersection point, and a minimum distance between the intersection point and the turning edge is in a range from 0.1 mm to 2.1 mm.

### CROSS REFERENCE TO RELATED APPLICATION

This application claims the benefits of the Taiwan Patent Application Serial Number 103123592, filed on Jul. 9, 2014, the subject matter of which is incorporated herein by reference.

This application also claims the benefit of filing date of U.S. Provisional Application Ser. No. 61/991,254, entitled “Free shaped display” filed May 9, 2014 under 35 USC §119(e)(1).

### BACKGROUND OF THE INVENTION

1. Field of the Invention

The present invention relates to a display panel and a method for cutting the same, and especially to a cutting method using arc-shaped cutting and a display panel formed thereby.

2. Description of Related Art

With the progressing development of display technology, all the devices are developed following the trend of minimization, thinness, light weight and so on, and the mainstream display devices has evolved from cathode ray tubes to the thin display devices. In particular, the thin display devices can be applied in various fields, such as a watch, a mobile phone, a notebook computer, a camcorder, a camera, a music player, a mobile navigation device, a television and the like used in daily life.

A typical display device commonly has a square structure. In recent years, to comply with the demand for aesthetics and design, the display device has been designed as various different shapes, such as round, triangular, diamond and so on. However, all display devices need to be cut out from a mother substrate, regardless of the shape of the display device.

The conventional cutting process of the mother substrate is commonly performed by rectangular cutting or cross-shaped cutting. However, the substrate of the display device formed by such a method usually have defects such as flanges and serrations etc., resulting in problems of an undesirable product appearance or a reduced cutting yield.

In view of the above, what is needed in the art is to develop a method for cutting a display panel and the display panel prepared thereby, which can solve the aforementioned problems and elevate the cutting yield.

### SUMMARY OF THE INVENTION

An object of the present invention is to provide a display panel and a method for cutting the same, so as to solve the aforementioned problems of flanges and serrations etc. caused by the conventional cutting method.

To achieve the above object, the method for cutting a display panel of the present invention comprises the following steps: providing a first mother substrate and a second mother substrate disposed opposite to each other; cutting the first mother substrate and the second mother substrate respectively, to obtain a first substrate and a second substrate respectively; wherein the first mother substrate is cut out with a first side, a turning edge having a curve shape with a first curvature radius, and a first edge, wherein the turning edge is between and connects the first side and the first edge, and the second substrate is protruded from the turning edge at a region near to the turning edge of the first substrate; wherein the second mother substrate is cut out with a second edge partially overlapped with the first edge; wherein a virtual extension line of the first side and the second edge intersect at an intersection point, and a minimum distance between the intersection point and the turning edge is in a range from 0.1 mm to 2.1 mm.

Through the aforementioned steps, the display panel of the present invention can be obtained, which comprises: a first substrate comprising at least a first side, a first edge, and a turning edge connecting the first side and the first edge, wherein the turning edge has a curve shape; and a second substrate disposed opposite to the first substrate and comprising at least a second edge partially overlapped with the first edge, wherein the second substrate is protruded from the turning edge at a region near to the turning edge of the first substrate, wherein a virtual extension line of the first side and the second edge intersect at an intersection point, and a minimum distance between the intersection point and the turning edge is in a range from 0.1 mm to 2.1 mm.

Furthermore, through the aforementioned steps, another display panel of the present invention may be obtained, which comprises: a first substrate comprising at least a first side, a first edge, and a turning edge connecting the first side and the first edge, wherein the turning edge has a curve shape; and a second substrate disposed opposite to the first substrate and comprising at least a second edge partially overlapped with the first edge, wherein the second substrate is protruded from the turning edge at a region near to the turning edge of the first substrate, wherein a curvature radius of the turning edge is different from that of the first edge.

In an embodiment of the invention, the display panel can have both characteristics that a minimum distance between the intersection point and the turning edge is in a range from 0.1 mm to 2.1 mm and a curvature radius of the turning edge is different from that of the first edge.

In the display panel and the method for cutting the same according to the present invention, the minimum distance between the turning edge and the intersection point formed by a virtual extension line of the first side and the second edge may be in a range from 0.1 mm to 2.1 mm; preferably from 0.1 mm to 1.3 mm; more preferably from 0.1 mm to 0.3 mm.

Furthermore, in the method for cutting a display panel according to the present invention, the second mother substrate may be further cut out with another turning edge having a curve shape with a second curvature radius. In this case, the first curvature radius for cutting the first mother substrate, the second curvature radius for cutting the second mother substrate, and the curvature radius of the turning edge having a curve shape, each can be in the ranges between 2.5 mm and 10 mm, preferably between 3 mm and 9 mm; and more preferably between 3 mm and 5 mm. The first curvature radius and the second curvature radius may be the same or different.

In addition, in the display panel and the method for cutting the same according to the present invention, the included angle between the first side or the virtual extension line thereof of the first substrate and the second edge of the second substrate can be between 30° and 170°.

### BRIEF DESCRIPTION OF THE DRAWINGS

FIG. 1 shows a cross sectional view of the display panel according to a preferred embodiment of the present invention before cutting.

FIG. 2 shows a top view of the display panel according to a preferred embodiment of the present invention after cutting.

FIG. 3 shows an enlarged view of a part of the display panel according to a preferred embodiment of the present invention.

FIGS. 4 to 9 show the schematic views of the display panels according to other preferred embodiments of the present invention.

### DETAILED DESCRIPTION OF THE PREFERRED EMBODIMENT

Hereinafter, exemplary examples of the present invention will be described in detail. However, the present invention is not limited to the examples disclosed below, but can be implemented in various forms. The following examples are described in order to enable those of ordinary skill in the art to embody and practice the present invention, and those skilled in the art will appreciate that various modifications, additions and substitutions are possible.

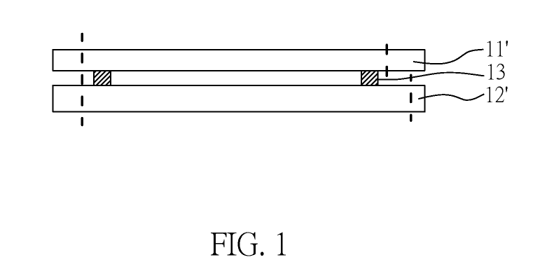

FIG. 1 shows a cross sectional view of the display panel according to a preferred embodiment of the present invention before cutting. In this embodiment, a first mother substrate 11′ and a second mother substrate 12′ are first provided, and assembled by a sealant 13, such that the first mother substrate 11′ and the second mother substrate 12′ are disposed opposite to each other. Here, the elements known in the art may be formed on the first mother substrate 11′ and the second mother substrate 12′ respectively. For example, if the display panel of this embodiment is a liquid crystal display panel, one of the first mother substrate 11′ and the second mother substrate 12′ may be an array having a thin film transistor unit disposed thereon, and another may be a substrate having a color filter and a black matrix disposed thereon. Alternatively, one of the first mother substrate 11′ and the second mother substrate 12′ may be a color filter on array (COA) substrate having both a thin film transistor unit and a color filter disposed thereon, and another may be a substrate having a black matrix formed thereon. In this case, the space defined by the first mother substrate 11′, the second mother substrate 12′ and the sealant 13 may be further filled with liquid crystal molecules. If the display panel of this embodiment is an organic light emitting diode display panel, the organic light emitting unit may be further disposed on one of the first mother substrate 11′ and the second mother substrate 12′. Here, both the liquid crystal display (LCD) panel and the organic light emitting diode display panel may have the common structure of a conventional liquid crystal display (LCD) panel or organic light emitting diode display panel, and it will not be described in detail.

Then, the first mother substrate 11′ and the second mother substrate 12′ are cut along the dashed lines in FIG. 1 respectively, to obtain a first substrate 11 and a second substrate 12 respectively, as shown in FIG. 2 which is a top view of the display panel according to a preferred embodiment of the present invention after cutting.

As shown in FIG. 1 and FIG. 2, the first mother substrate 11′ is cut from the starting point S1 along the direction indicated by the arrow and back to the starting point S1 by a single cut, to obtain the first substrate 11. First, starting at the starting point S1, the first cutting edge 113 is cut out by a curvature radius; and then, the turning edge 112a having a curve shape is cut out by a first curvature radius at the turning part 11a (as shown by the left turning part 11a in FIG. 2), to form a chamfer. Then, a straight first side 111 is cut out, and the turning edge 112b having a curve shape is cut out by a first curvature radius or other curvature radius at the turning part 11b (as shown by the right turning part 11b in FIG. 2), to form another chamfer. Finally, the cutting is performed using the same curvature radius for cutting the first edge 113, and back to the starting point S1. In this embodiment, the turning edge 112a is connected to an end of the first side 111, and the turning edge 112b is connected to another end of the first side 111. In this embodiment, the two ends of the first side 111 are formed into the turning edges 112a, 112b having a curve shape or chamfer, respectively. Here, the curvature radius for cutting the first edge 113 is different from the first curvature radius for forming the turning edges 112a, 112b having a curve shape; and preferably the curvature radius for cutting the first edge 113 is larger than the first curvature radius for forming the turning edges 112a, 112b having a curve shape.

In addition, when the second mother substrate 12′ is cut for the second substrate 12, the cutting may also be performed from the same starting point S1 for cutting the first mother substrate 11′ along the direction indicated by the arrow by a single cut. In this case, the second mother substrate 12′ is cut by a second curvature radius at the turning parts 12a, 12b to form turning edges 122a, 122b or chamfers, and the second mother substrate 12′ is cut by the same curvature radius for forming the first edge 113 of the first substrate 11, to form a second edge 122 which is partially overlapped with the first edge 113. Here, the second substrate 12 is protruded from the turning edges 112a, 112b.

In this embodiment, the first curvature radius for forming the first turning edges 112a, 112b of the first substrate 11 may be the same as or different from the second curvature radius for forming the second turning edges 122a, 122b of the second substrate 12, and the first curvature radius and the second curvature radius may be in a range between 2.5 mm and 10 mm respectively, preferably between 3 mm and 9 mm, and most preferably between 3 mm and 5 mm. Accordingly, in the obtained display panel, the curvature radius of the first turning edges 112a, 112b having a curve shape of the first substrate 11 and the curvature radius of the second turning edges 122a, 122b having a curve shape of the second substrate 12 may also be the same or different, and the curvature radius of the first turning edges 112a, 112b of the first substrate 11 and the curvature radius of the second turning edges 122a, 122b of the second substrate 12 may be in a range between 2.5 mm and 10 mm respectively, preferably between 3 mm and 9 mm, and most preferably between 3 mm and 5 mm.

In this embodiment, the first mother substrate 11′ and the second mother substrate 12′ are cut from the same starting point S1. However, in other embodiments of the present invention, the first mother substrate 11′ and the second mother substrate 12′ may be cut from different starting points S1, or the first mother substrate 11′ and the second mother substrate 12′ may be cut from a starting point S1 located elsewhere of the display panel, as long as the cuttings of the first mother substrate 11′ and the second mother substrate 12′ are performed at the turning parts 11a, 11b, 12a, 12b by the first curvature radius and the second curvature radius.

When the traditional rectangular cutting is applied in the contour cutting, the problems such as flanges and serrations etc. may occur at the site near the cross-shaped cutting position. However, in this embodiment, the arc contour cutting (R angle or chamfer cutting) of the substrate is performed at a first turning part by the first curvature radius and the second curvature radius, to reduce the issues such as flanges and serrations etc., thereby increasing the cutting yields, and optimizing the cutting quality.

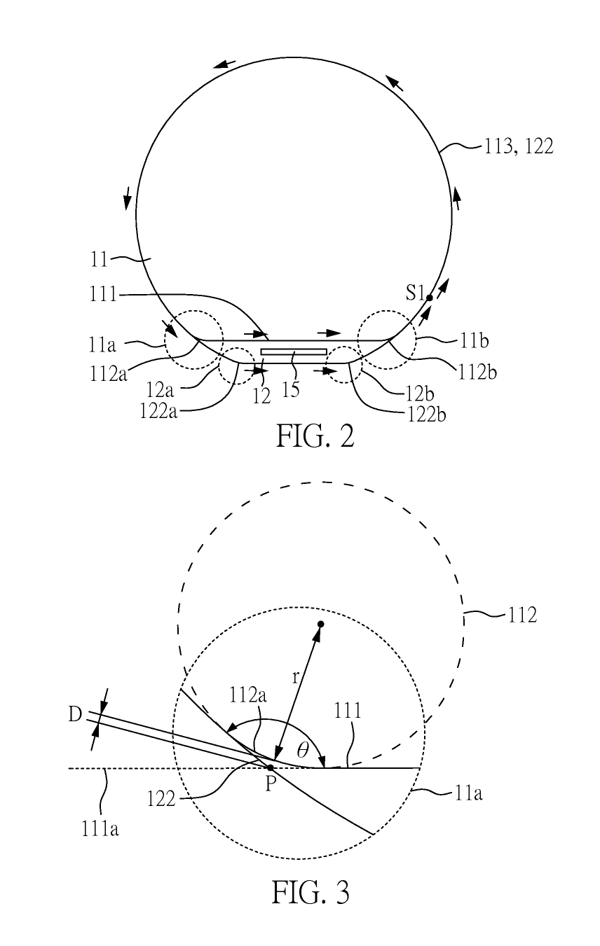

In the present invention, the term “turning part” refers to a part where an included angle is formed by two adjacent sides being 30° to 170°. Through the aforementioned steps, the display panel of the present embodiment can be obtained. As shown in FIG. 2 and FIG. 3, in which FIG. 3 is an enlarged view of region of the turning part 11a of FIG. 2, the display panel of this embodiment comprises: a first substrate 11 comprising at least a first side 111, a first edge 113, and a turning edge 112a connecting the first side 111 and the first edge 113, wherein the turning edge 112a has a curve shape; and a second substrate 12 disposed opposite to the first substrate 11 and comprising at least a second edge 122 partially overlapped with the first edge 113, wherein the second substrate 12 is protruded from the turning edge 112a at a region near to the turning edge 112a of the first substrate 11, wherein an extension (as shown by the dashed line in FIG. 3) of the first side 111 and the second edge 122 intersect at an intersection point P, and a minimum distance between the intersection point P and the turning edge 112a is in a range from 0.1 mm to 2.1 mm (preferably between 0.1 mm and 1.3 mm, and more preferably between 0.1 mm and 0.3 mm). In addition, the curvature radius of the turning edge 112a is different from the curvature radius of the first edge 113. Furthermore, in the display panel of the present embodiment, the included angle between the first side 111 and the second edge 122 of the second substrate 12 can be 30° to 170°.

In this embodiment, as shown in FIG. 3, taking the turning part 11a of the first substrate 11 as an example, the arc-shaped turning edges 112a may correspond to an osculating circle 112 having a radius r which is the curvature radius for forming the arc-shaped turning edge 112a. Similarly, another turning part 11b of the first substrate 11 and the turning parts 12a, 12b of the second substrate may also correspond to another osculating circle having a radius which is the curvature radius for forming the arc-shaped turning edge.

In this embodiment, both the first curvature radius for forming the turning edges 112a, 112b of the first substrate 11 and the curvature radius for forming the turning edges 122a, 122b of the second substrate 12 are 3 mm, and thus both the chamfers of the first substrate 11 and second substrate 12 have a curvature radius of 3 mm; while a minimum distance between the turning edge 112a and the intersection point P formed by a virtual extension line of the first side 111 and the second edge 122 is in a range from 0.1 mm to 0.3 mm, and the included angle θ between the first side 111 and the second edge 122 of the second substrate 12 is 30° to 170°. Furthermore, a terminal part 15 is further formed on the second substrate 12.

The curvature radius for forming the first edge 113 and the second edge 122 is not particularly limited, and may depend on the desired shape of the display panel.

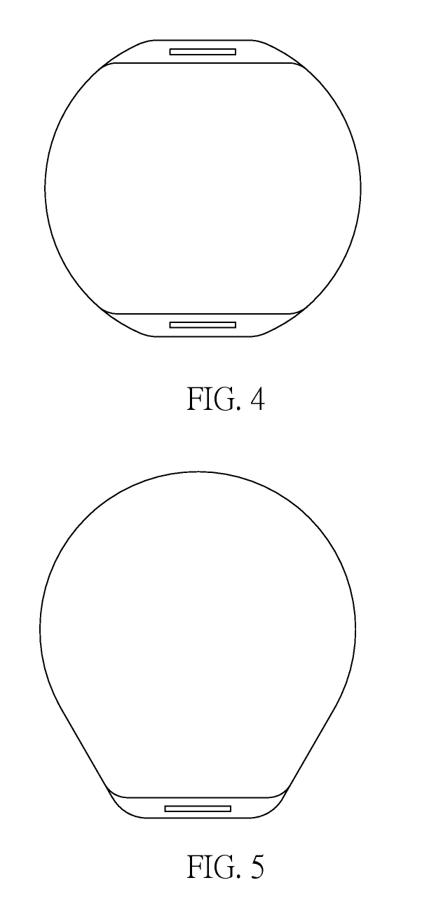

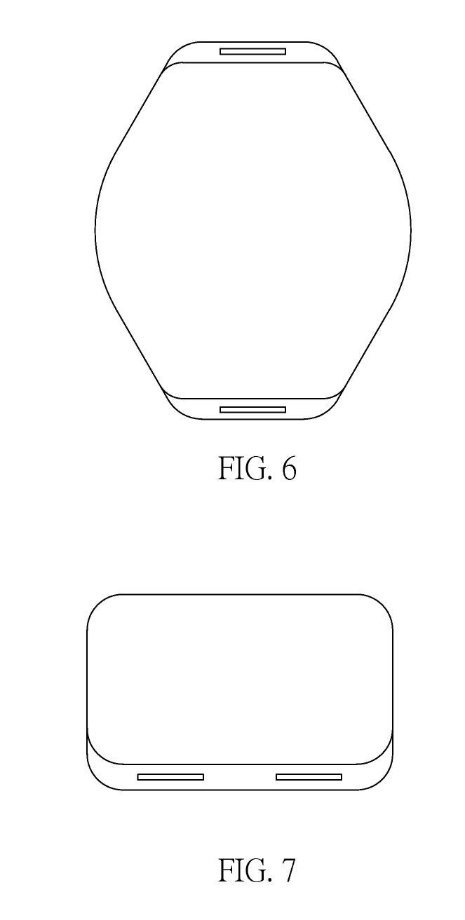

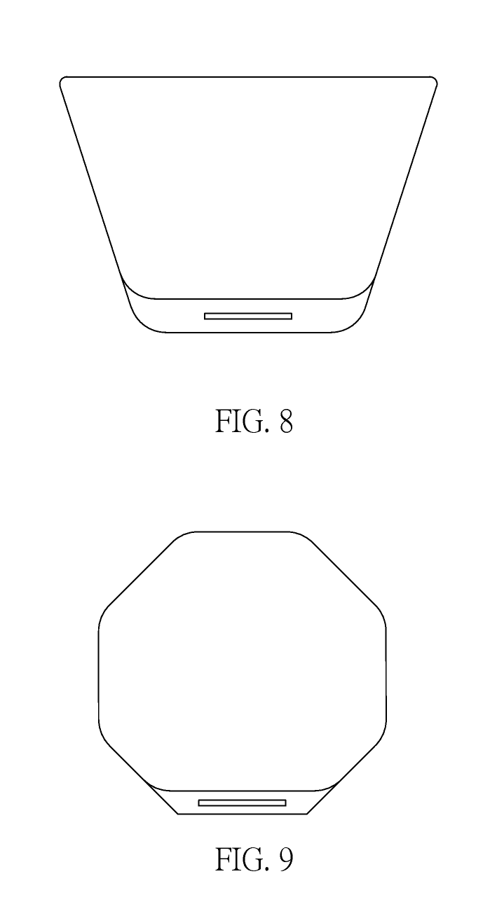

In the present invention, in addition to the display panel as shown in FIG. 2, the display panel including two terminal parts 15 as shown in FIG. 3, and the display panels having a different shapes as shown in FIGS. 4 to 9, may also be formed, as long as the aforementioned arc edges or chamfer can be formed at the turning part to reduce the issues such as flanges and serrations etc., thereby achieving the objects of increasing the cutting yields, and optimizing the cutting quality.

In addition, the display panel prepared by the aforementioned embodiments of the present invention can be applied to any conventional electronic device requiring a display screen, such as a monitor, a cell phone, a notebook computer, a camcorder, a camera, a music player, a mobile navigation device, a television, a watch, and so on.

While the invention has been shown and described with reference to certain exemplary examples thereof, it will be understood by those skilled in the art that various changes in form and details may be made therein without departing from the scope of the invention as defined by the appended claims.

What is claimed is:

1. A display panel, comprising:
a first substrate comprising at least a first side, a first edge, and a turning edge connecting the first side and the first edge, wherein the turning edge has a curve shape; and
a second substrate disposed opposite to the first substrate and comprising at least a second edge partially overlapped with the first edge, wherein the second substrate is protruded from the turning edge at a region near to the turning edge of the first substrate,
wherein a virtual extension line of the first side and the second edge intersect at an intersection point, and a minimum distance between the intersection point and the turning edge is in a range from 0.1 mm to 2.1 mm.

2. The display panel of claim 1, wherein the minimum distance between the intersection point and the turning edge is in a range from 0.1 mm to 1.3 mm.

3. The display panel of claim 2, wherein the minimum distance between the intersection point and the turning edge is in a range from 0.1 mm to 0.3 mm.

4. The display panel of claim 1, wherein the turning edge has a curvature radius of 2.5 mm to 10 mm.

5. A display panel, comprising:
a first substrate comprising at least a first side, a first edge, and a turning edge connecting the first side and the first edge, wherein the turning edge has a curve shape; and
a second substrate disposed opposite to the first substrate and comprising at least a second edge partially overlapped with the first edge, wherein the second substrate is protruded from the turning edge at a region near to the turning edge,
wherein a curvature radius of the turning edge is different from that of the first edge.

6. The display panel of claim 5, wherein the turning edge has a curvature radius of 2.5 mm to 10 mm.

7. A method for cutting a display panel, comprising:
providing a first mother substrate and a second mother substrate disposed opposite to each other;
cutting the first mother substrate and the second mother substrate respectively, to obtain a first substrate and a second substrate respectively;
wherein the first mother substrate is cut out with a first side, a turning edge having a curve shape with a first curvature radius, and a first edge, wherein the turning edge is between and connects the first side and the first edge, and the second substrate is protruded from the turning edge at a region near to the turning edge of the first substrate;
wherein the second mother substrate is cut out with a second edge partially overlapped with the first edge;
wherein a virtual extension line of the first side and the second edge intersect at an intersection point, and a minimum distance between the intersection point and the turning edge is in a range from 0.1 mm to 2.1 mm.

9. The method of claim 7, wherein the minimum distance between the intersection point and the turning edge is in a range from 0.1 mm to 1.3 mm.

9. The method of claim 8, wherein the minimum distance between the intersection point and the turning edge is in a range from 0.1 mm to 0.3 mm.

10. The method of claim 1, wherein the first curvature radius is in a range from 2.5 mm to 10 mm.
